(19) United States
(12) Patent Application Publication
(10) Pub. No.: US 2010/0103593 A1
(43) Pub. Date: Apr. 29, 2010

(54) PORTABLE ELECTRONIC DEVICE

(75) Inventors: CHIH-CHIANG CHANG, Shindian (TW); ZHI LI, Shenzhen City (CN); ZHI-YUN SHEN, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/345,392

(22) Filed: Dec. 29, 2008

(30) Foreign Application Priority Data
Oct. 23, 2008 (CN) 200810305101.4

(51) Int. Cl. H05K 7/00

(52) U.S. Cl. 361/679.01

(57) ABSTRACT

A portable electronic device is provided. The portable electronic device includes a body member, a shaft mounted to the body member and a cover member pivotally connected to the body member by the shaft to close or expose an opening defined in the body member.

### BACKGROUND

1. Field of the Invention

The present invention relates to portable electronic devices and, particularly, to a portable electronic device with a cover assembly.

2. Description of Related Art

Chip cards such as memory cards are typically inserted and secured in an accommodating compartment of a portable electronic device such as a mobile phone.

The accommodating compartment often includes an exposed opening for insertion of the chip card or a peripheral connector and a receiving space communicating with the opening. The accommodating compartment further has a cover member to close off the opening to prevent e.g., water or dust from entering into the receiving space.

However, the cover member is typically made of rubber. After repeatedly usage, the cover member tends to be worn out and not function properly.

Therefore, there is room for improvement within the art.

### BRIEF DESCRIPTION OF THE DRAWINGS

Many aspects of the portable electronic device can be better understood with reference to the following drawings. These drawings are not necessarily drawn to scale, the emphasis instead being placed upon clearly illustrating the principles of the present portable electronic device. Moreover, in the drawings like reference numerals designate corresponding sections throughout the several views.

FIG. 1 is an exploded, isometric view of a portable electronic device, in accordance with an exemplary embodiment.

FIG. 2 is another exploded, isometric view of the portable electronic device shown in FIG. 1.

FIG. 3 is an isometric, assembled view of the portable electronic device shown in FIG. 1.

FIG. 4 is a schematic view showing the usage of the portable electronic device shown in FIG. 3.

### DETAILED DESCRIPTION OF EXEMPLARY EMBODIMENT

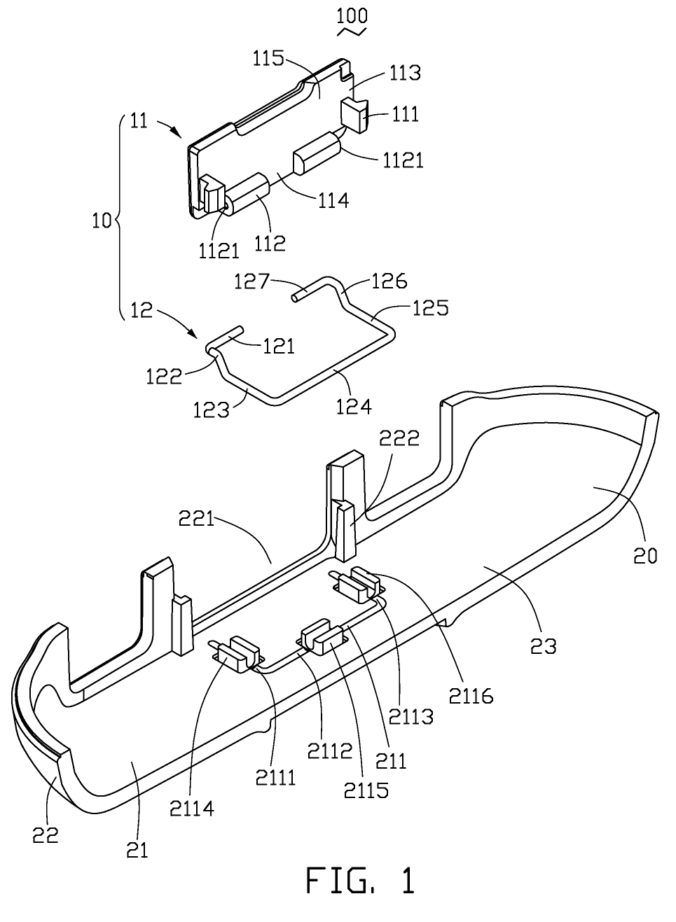

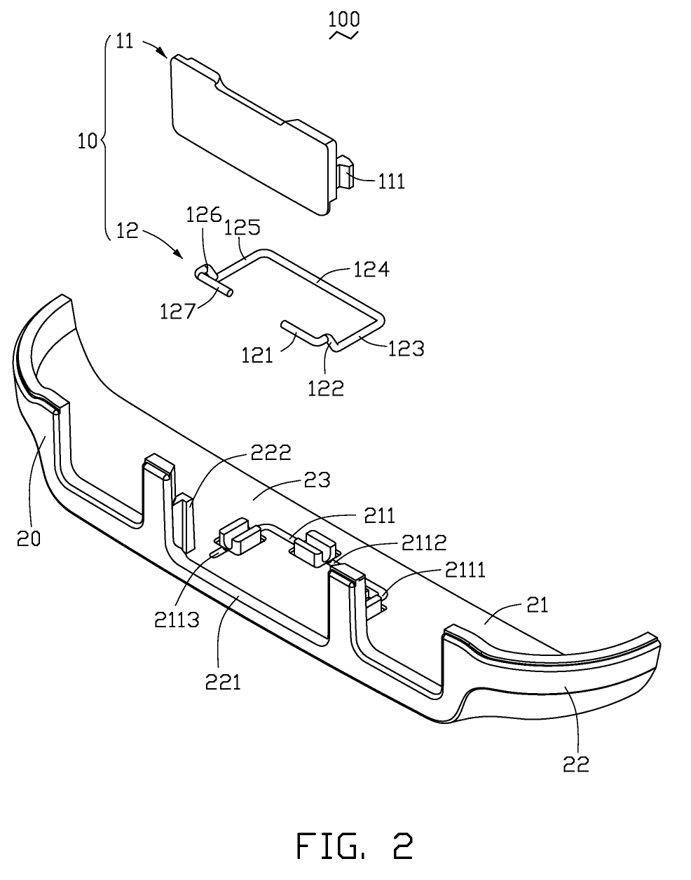

FIGS. 1 and 2 show an exemplary portable electronic device 100. The portable electronic device 100 includes a cover assembly 10 and a body member 20. The cover assembly 10 is assembled to the body member 20. The body member 20 is taken here as an exemplary application, for the purpose of describing details of the cover assembly 10 of an exemplary embodiment. The cover assembly 10 includes a cover member 11 and a shaft 12. The cover member 11 can be pivotally connected to the body member 20 via the shaft 12.

The shaft 12 is generally a bent bar. The shaft 12 includes a head portion 121, a first connecting portion 122, a first mounting portion 123, a second mounting portion 124, a third mounting portion 125, a second connecting portion 126 and a tail portion 127. The first mounting portion 123 is parallel with and connected to the third mounting portion 125 by the mounting portion 124. Each of the first mounting portion 123 and the third mounting portion 125 is perpendicular with the second mounting portion 124. The first connecting portion 122 extends out of the plane of the first mounting portion 123. The head portion 121 perpendicularly connects to the first connecting portion 122. The second connecting portion 126 extends out of the plane of the third mounting portion 125. The tail portion 127 perpendicularly connects to the second connecting portion 126 towards the head portion 121.

The cover member 11 is substantially rectangular and includes two L-shaped elastic latching portions 111 and two fastening portions 112. The latching portions 111 protrude from an inner surface 115 of the cover member 11 and are adjacent to two opposite first edges 113 of the cover member 11. The fastening portions 112 protrude from the inner surface 115 of the cover member 11 and are adjacent to a second edge 114. The first edges 113 are perpendicular to the second edge 114. The fastening potions 112 are arranged between the two latching portions 111. Each fastening portion 112 defines a circular, blind fastening hole 1121 facing corresponding latching portion 111. The fastening holes 1121 pivotally receive the head portion 121 and the tail portion 127 of the shaft 121, respectively.

The body member 20 includes a bottom wall 21 and a peripheral wall 22, and defines a receiving compartment 23 enclosed by the bottom wall 21 and the peripheral wall 22. The peripheral wall 22 defines an opening 221 communicating with the receiving compartment 23. The opening 221 is used to facilitating of insertion of all kinds of chip cards or peripheral connectors. The opening 221 can be closed off by the cover assembly 10. Two L-shaped latches 222 protrude from opposite sides of the opening 221, and interlock with the latching portions 111 of the cover member 11. The bottom wall 21 defines a mounting slot 211, configured to mount the shaft 12 therein. The mounting slot 211 includes a first slot section 2111, a second slot section 2112 and a third slot section 2113. The first slot section 2111, the second slot section 2112 and the third slot section 2113 correspond to the first mounting portion 123, the second mounting portion 124 and the third mounting portion 125 of the shaft 12, respectively. Two parallel first fastening boards 2114 are oppositely secured on sides of the first slot section 2111, corresponding to the first mounting portion 123. Two parallel second fastening boards 2115 are oppositely secured on sides of the second slot section 2112, corresponding to the second mounting portion 124. Two parallel third fastening boards 2113 are oppositely secured on sides of the third slot section 2116, corresponding to the third mounting portion 125.

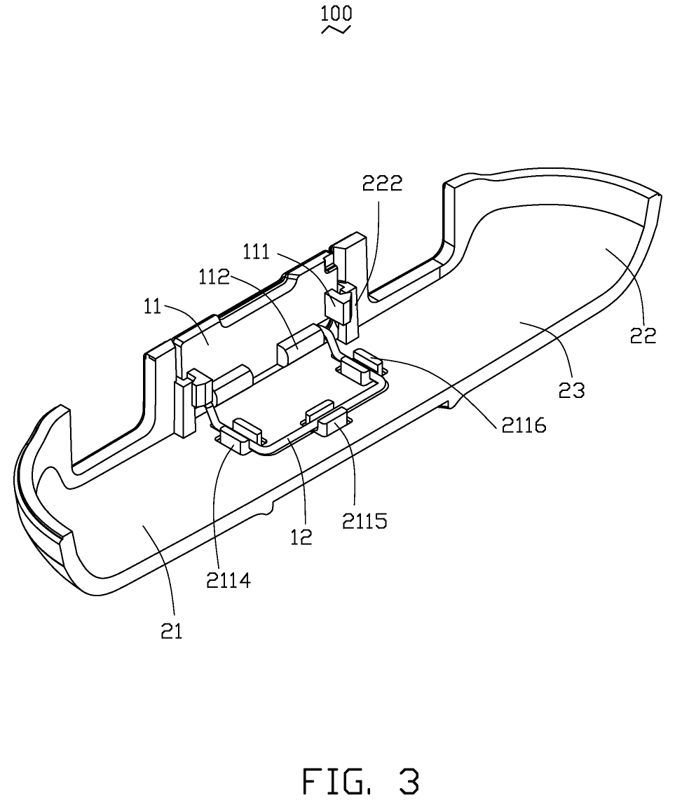

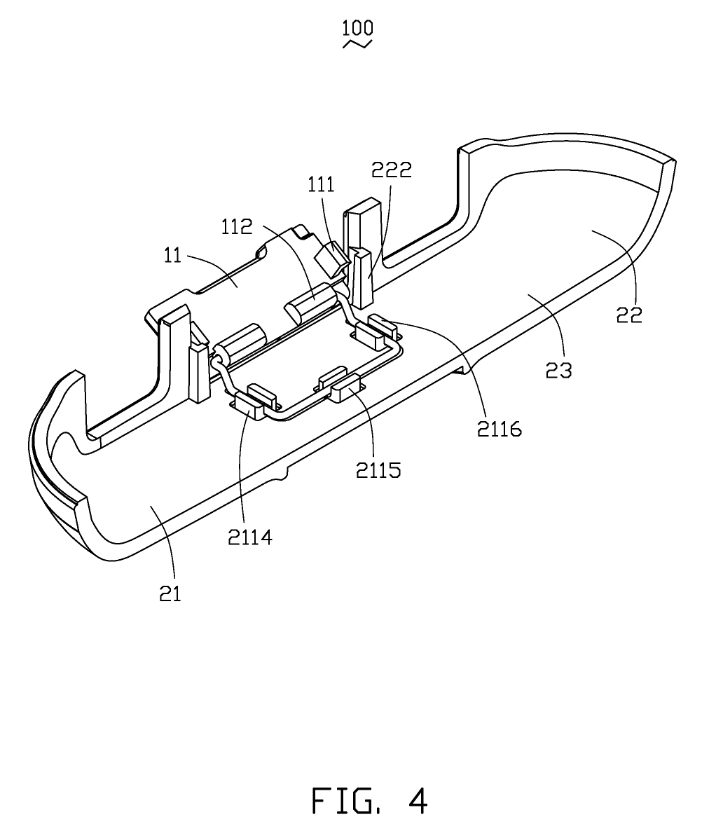

Referring to FIGS. 3 and 4, the head portion 121 and the tail portion 127 are inserted into the mounting holes 1121. At this time, the mounting slot 211 receives the shaft 12 therein. The first mounting portion 123, the second mounting portion 124 and the third mounting portion 125 are fixed to the body member 20 by, e.g., by hot-melting, the first fastening boards 2114, the second fastening boards 2115 and the third fastening boards 2116 around portions of the shaft 12. Therefore, the cover member 11 can pivot on the shaft 12 to close the opening 221 and additionally latch to the body member 20 by interlocking of the latching portions 111 and the latches 222.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of sections within the principles of the invention to the full extent indicated by the broad general meaning of the terms, in which the appended claims are expressed.

What is claimed is:

1. A portable electronic device, comprising:
a body member defining an opening;
a shaft being mounted to the body member and adjacent to the opening; and
a cover member pivotally connected to the body member by the shaft to close or expose the opening.

2. The portable electronic device as claimed in claim 1, wherein the cover member has two fastening portions facing the body member, each fastening portion defining a fastening hole to pivotally receive the shaft.

3. The portable electronic device as claimed in claim 1, wherein the cover member includes a latching portion, the body member includes a latch adjacent to the opening, the latch detachably latches the latching portion.

4. The portable electronic device as claimed in claim 1, wherein the body member defines a mounting slot configured to receive a portion of the shaft.

5. The portable electronic device as claimed in claim 4, wherein fastening boards are arranged on opposing sides of the mounting slot, the shaft being fixed to the body member by hot-melting the fastening boards around portions of the shaft.

6. The portable electronic device as claimed in claim 2, wherein the shaft is generally a bent bar.

7. The portable electronic device as claimed in claim 6, wherein the shaft includes a head portion and a tail portion opposite to the head portion, the head portion and the tail portion are pivotally received in the fastening holes.

8. The portable electronic device as claimed in claim 7, wherein the shaft further includes a mounting portion, used to mount the shaft to the body member.

9. The portable electronic device as claimed in claim 8, wherein the shaft further includes a first connecting portion and a second connecting portion, the first connecting portion extends out of the plane of one end of the mounting portion, the second connecting portion extends out of the plane of the other end of the mounting portion, the head portion perpendicularly connects to the first connecting portion, the tail portion perpendicularly connects to the second connecting portion towards the head portion.
